(19) United States
(12) Patent Application Publication
(10) Pub. No.: US 2016/0225965 A1
(43) Pub. Date: Aug. 4, 2016

(54) PACKAGING STRUCTURE OF LIGHT EMITTING DIODES AND METHOD THEREFOR

(71) Applicant: Unistars Corporation, Hsinchu County (TW)

(72) Inventors: WEN-CHENG CHIEN, Hsinchu City (TW); SHANG-YI WU, Hsinchu City (TW)

(21) Appl. No.: 14/709,477

(22) Filed: May 12, 2015

(30) Foreign Application Priority Data
Jan. 30, 2015 (TW) 104103314

(51) Int. Cl. H01L 33/58; H01L 33/08; H01L 33/36; H01L 33/62; H01L 33/44

(52) U.S. Cl. CPC H01L 33/58; H01L 33/62; H01L 33/44; H01L 33/36; H01L 33/08; H01L 2933/0016; H01L 2933/0025; H01L 2933/0066

(57) ABSTRACT

A packaging method for light emitting diodes and structure thereof are provided, more particularly, provided are packaging method and structure thereof, which innovates packaging processes in fabrication distinct from and even contrary to those of conventional technologies, and obviate required Gold Wire Bonding Processes traditionally. The method comprises steps of: (A) preparing a transparent substrate with high transparency, (B) providing an optoelectronic semiconductor chip on a surface of the transparent substrate the optoelectronic semiconductor chip being provided with a light-emitting face and at least two electrodes, wherein a light emitted from the optoelectronic semiconductor chip penetrates through the transparent substrate, (C) providing an insulating layer on the transparent substrate, so as to partially overlay on the at least two electrodes, the optoelectronic semiconductor chip and the transparent substrate, and (D) and the at least two metal soldering pads being electrically connected with the at least two electrodes respectively.

### FIELD OF THE INVENTION

The invention relates to a packaging structure of light emitting diodes and method therefor, and more particularly to packaging structure and method therefor, which innovate packaging processes in fabrication distinct from and even contrary to those of conventional technologies, and obviate conventional gold wire bonding processes.

### BACKGROUND OF THE INVENTION

Light emitting diode (LED) is an luminescent semiconductor electronics, known for its advantages of energy-saving, power-saving, high-efficiency, prompt response time, prolonged life time, free of mercury, benefit to environment protection, and is recently applied to illumination. Generally, not only LED packaging is requested for one function of sheltering LED chips, but also for the special properties of material, such as transparency thereof, encapsulating method and structure.

In a general LED packaging technology, it often involves employing an opaque patterned substrate for carrying the LED chips and electrodes thereon, encapsulating the chips, metal wiring and the opaque substrate thoroughly, those are provided on the opaque substrate and the chips, by use of transparent materials after electrically connecting LED chips with electrodes via metal wiring, and accomplishing the packaging via curing. It becomes necessary for LED packaging to use transparent materials due to requirements of passing-through for light and functioning as a lens concurrently, and it will be unable to adopt opaque metal materials with an excellent heat dissipation effect, resulting in imposing the heat dissipation of LED chips on the opaque patterned substrate. However, in the conventional technologies, the opaque patterned substrate is generally made of non-metallic materials, such as epoxy molding compound, alumina (Al₂O₃), etc., leading to a poor heat dissipation efficiency of LED chips those are sandwiched between the substrate and packaging material layer. In addition, since the metal wiring is encapsulated in the packaging materials, it is thus possible to cause fractures or displacement in the metal wiring due to the occurrence of thermal expansion and cold shrinkage in the packaging materials, resulting in problems of, e.g. poor contact and so on.

FIGS. 6A and 6B are two structures of light emitting diodes produced by conventional packaging methods, and the differences therebetween merely reside in the existence of isolator structure or not, and shapes of the packaging material layer originated from the transparent material via curing.

As illustrated in FIG. 6A, an electrode 112, an LED die 113 and a metal wiring 114 have been provided on an opaque patterned substrate 111, and, in order to allow transparent encapsulating layer material to fill in the space between the electrode 112, the LED die 113 and the metal wiring 114 thoroughly over the opaque patterned substrate 111, a frame 115 is thus provided on the opaque patterned substrate 111 so as to encircle the LED die 113, eventually, it is possible to produce a transparent encapsulating layer 116 via curing the transparent encapsulating layer material that is filled in the encircled space and accomplish a fabricated finished packaging structure. However, not only such a structure of light emitting diode as produced will suffer from the aforementioned problems, but also the frame 115 thereof is necessarily higher than the LED die 113 so as to allow the transparent encapsulating layer material to cover over the LED die 113 and function itself as a lens and a shelter, while it is also necessarily higher than the metal wiring 114 for sheltering the structure of light emitting diode, resulting in a considerable limitation in size via packaging.

Furthermore, as illustrated in FIG. 6B, an electrode 122, an LED chip 123 and a metal wiring 124 have been provided on an opaque patterned substrate 121, and a dome-shaped transparent encapsulating layer 126 is then produced via molding, so that it is possible to obviate the cost and processes of fabricating a frame, while it is beneficial to modify irradiation direction of light by use of the dome-shaped structure of the transparent encapsulating layer 126. However, even such a structure of light emitting diode as produced, it is still hard to overcome the problems as occurred in the aforementioned LED chips, such as a poor heat dissipation efficiency, fractures or displacement in the metal wiring and a poor contact, additionally, under the circumstances of necessity for the transparent encapsulating layer 126 to encapsulate the LED chips 123 and the metal wiring 124 thoroughly and a required curvature thereof by the desired irradiation direction of light, it becomes impossible to further alleviate the limitation in size via packaging. In the wake of developments in technology, it thus becomes an object of the invention, that is, to achieve an increase in quality of product and robustness thereof, as well as the reduction of size in packaging, via solving the above problems, along with a prolonged quality of product and robustness thereof, meanwhile, on the trend of pursuing reduced weight and size of product.

### SUMMARY OF THE INVENTION

Therefore, in accordance with the invention, a packaging method for light emitting diodes is provided, which innovates packaging processes in fabrication distinct from conventional technologies, and obviate required Gold Wire Bonding Processes traditionally, for avoiding disadvantages of break, fractures or displacement in metal wiring, poor contact, tremendous volume of encapsulation, the excessive cost of gold wires and high production cost raised by complicated production processes those are resulted from the conventional technologies.

Moreover, according to the invention, a packaging structure of light emitting diodes is provided, where the substrate as employed in the conventional technologies can be omitted and replaced by a single transparent substrate that immediately functions as a carrier and also a lens due to transparency thereof, further, is superior to the conventional ones made by thermal curing silicone glue or epoxy glue in light transmittance for the material of glass is more pertinent to light transmission, and yet, there is no metal wiring in the structure according to the invention which is used in the conventional technologies, it will be thus free from disadvantages of break and fractures in metal wiring, etc., also feasible to achieve the increased robustness in quality.

Here, according to the invention, a packaging structure of light emitting diodes is provided, that comprises a transparent substrate, an optoelectronic semiconductor chip, provided with a light-emitting face and at least two electrodes, the at least two electrodes being provided on an opposite surface to an adjoining surface of the optoelectronic semiconductor chip and the transparent substrate, the light-emitting face being placed on the adjoining surface of the optoelectronic semiconductor chip and the transparent substrate, an insulating layer, being provided on the transparent substrate, partially overlaid on the at least two electrodes, the optoelectronic semiconductor chip and the transparent substrate, and metal soldering pads, being provided separately on the at least two electrodes, and electrically connected with the at least two electrodes respectively, wherein a light emitted from the optoelectronic semiconductor chip penetrates through the transparent substrate.

Further, according to the invention, a packaging method for light emitting diodes is provided, that comprises steps of: (A) preparing a transparent substrate with high transparency, (B) providing an optoelectronic semiconductor chip on a surface of the transparent substrate, the optoelectronic semiconductor chip being provided with a light-emitting face and at least two electrodes, the at least two electrodes being provided on an opposite surface to a joining surface of the optoelectronic semiconductor chip and the transparent substrate, the light-emitting face being placed on the joining surface of the optoelectronic semiconductor chip and the transparent substrate, wherein a light emitted from the optoelectronic semiconductor chip penetrates through the transparent substrate, (C) providing an insulating layer on the transparent substrate, so as to partially overlay on the at least two electrodes, the optoelectronic semiconductor chip and the transparent substrate, and (D) providing at least two metal soldering pads separately on the at least two electrodes, and the at least two metal soldering pads being electrically connected with the at least two electrodes respectively.

### BRIEF DESCRIPTION OF THE DRAWINGS

The invention will become more readily apparent to those ordinarily skilled in the art after reviewing the following detailed description and accompanying drawings, in which:

FIG. 1 is a flow chart depicting a packaging method for light emitting diodes according to the invention;

FIG. 2 is a cross-sectional view illustrating a packaging structure of light emitting diodes according to the invention;

FIGS. 3A-3G are sectional views illustrating the packaging structures of light emitting diodes corresponding to the packaging method according to the invention;

FIGS. 4A-4C and FIGS. 5A-5C are cross-sectional views illustrating the packaging structures of light emitting diodes according to various embodiments of the invention; and

FIGS. 6A-6B are laterally cross-sectional views illustrating conventional packaging structures of LEDs.

### DETAILED DESCRIPTION OF PREFERRED EMBODIMENTS

A packaging method for light emitting diodes and a structure thereof, according to the invention, are provided, in order to achieve reduction in volume, assistance in production, improvement in yield rate and prolonged robustness in quality of product even used. The embodiments will now be described more specifically with reference to the following embodiments. It is to be noted that the following descriptions of preferred embodiments are presented herein for purpose of illustration and description only. It is not intended to be exhaustive or to be limited to the precise form disclosed.

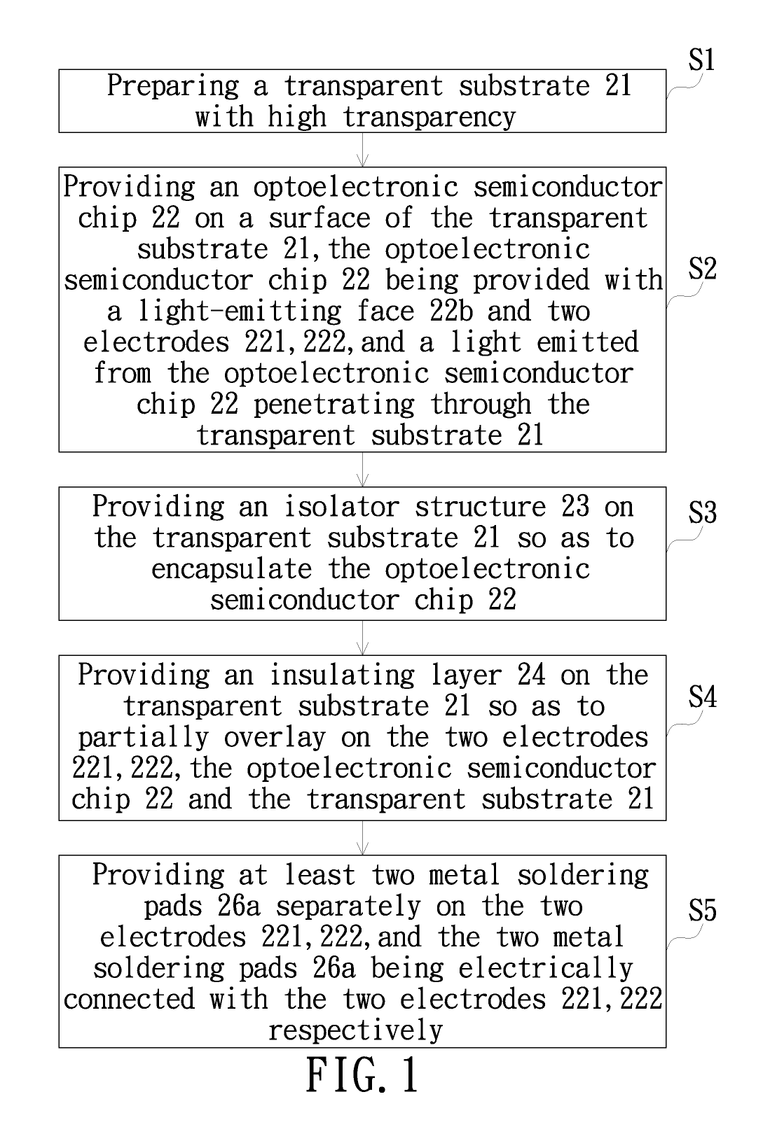

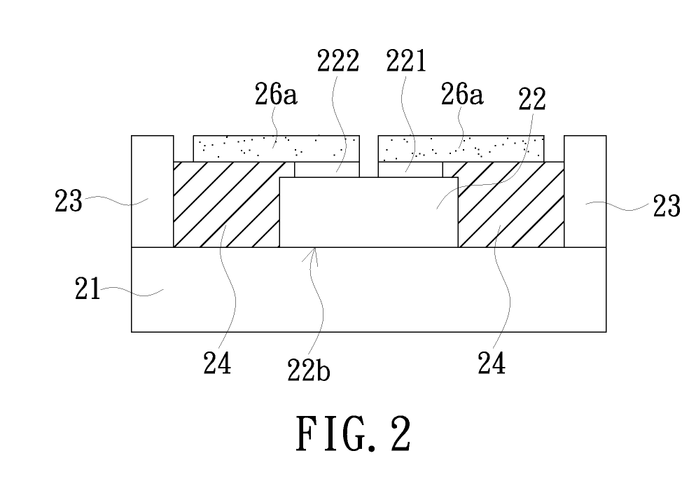

With reference to FIGS. 1 and 2 simultaneously, a flow chart depicting a packaging method for light emitting diodes and a drawing illustrating a packaging structure of light emitting diodes according to the invention are described. As illustrated in above drawings, the packaging method for light emitting diodes comprises the steps of (S1) preparing a transparent substrate 21 with high transparency, wherein the transparent substrate 21 is made of glass and preferably in the shape of a rectangular cuboid, a quadrangular pyramid or an arc-section cuboid, for modifying an irradiating direction of the light emitted from an optoelectronic semiconductor chip 22, (S2) providing the optoelectronic semiconductor chip 22 on one surface of the transparent substrate 21, wherein the optoelectronic semiconductor chip 22 is preferably an light emitting diode chip, which is provided with a light-emitting face 22b and two electrodes 221, 222, and the at least two electrodes 221, 222 are provided on an opposite surface to a joining surface of the optoelectronic semiconductor chip 22 and the transparent substrate 21, while the light-emitting face 22b is placed on the joining surface of the optoelectronic semiconductor chip 22 and the transparent substrate 21, and wherein a light emitted from the optoelectronic semiconductor chip 22 penetrates through the transparent substrate 21, (S3) providing an isolator structure 23 on the transparent substrate 21 so as to encircle the optoelectronic semiconductor chip 22, wherein the isolator structure 23 is provided on the transparent substrate 21 via any one method of printing, dispensing and lithography, (S4) providing an insulating layer 24 on the transparent substrate 21 so as to partially overlay on the at least two electrodes 221, 222, the optoelectronic semiconductor chip 22 and the transparent substrate 21, and (S5) providing at least two metal soldering pads 26a separately on the at least two electrodes 221, 222, and the metal soldering pads 26a being electrically connected with the at least two electrodes 221, 222 respectively.

As described, the above descriptions of packaging method and structure of light emitting diode are related to one method according to a first embodiment of the invention and one corresponding structure produced by the method according to the first embodiment of the invention. Nevertheless, it is alternative to produce a modified packaging structure of light emitting diodes without the isolator structure 23, by omitting the step of (S3), and thus, another method according to a second embodiment of the invention and another one corresponding structure produced by the method according to the second embodiment of the invention can be thereby derived.

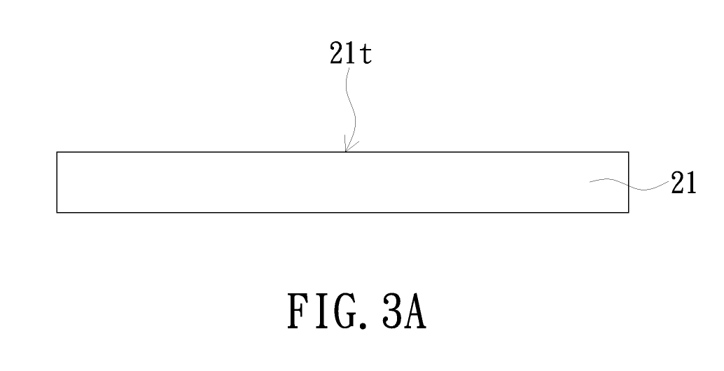

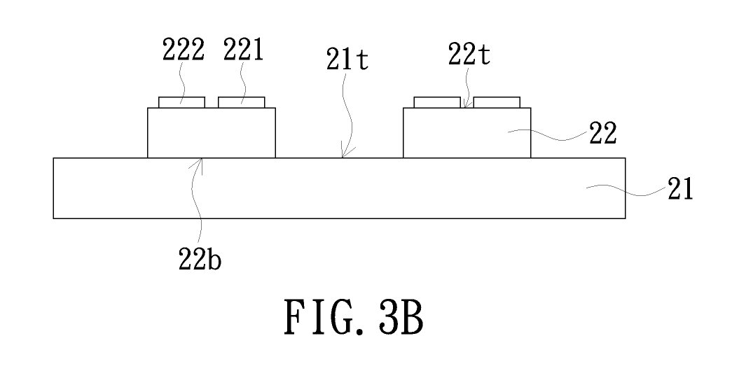

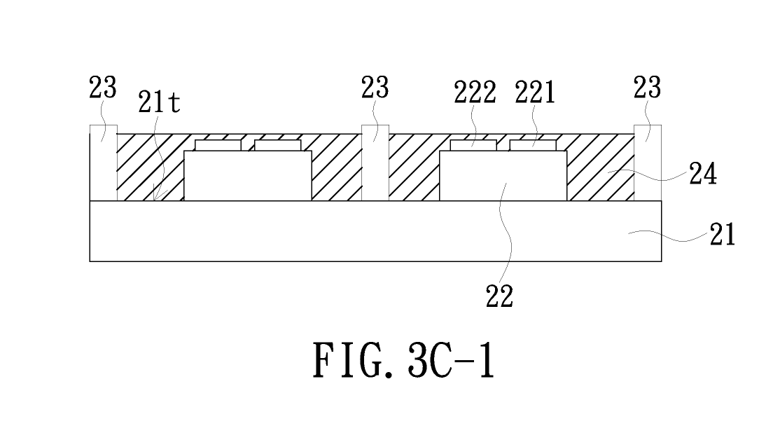

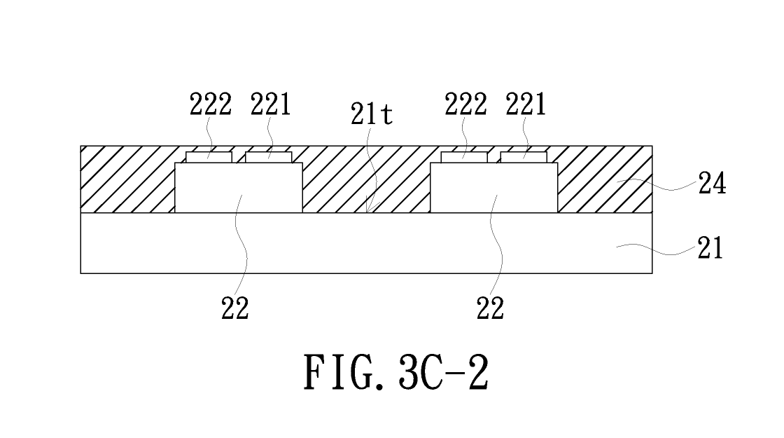

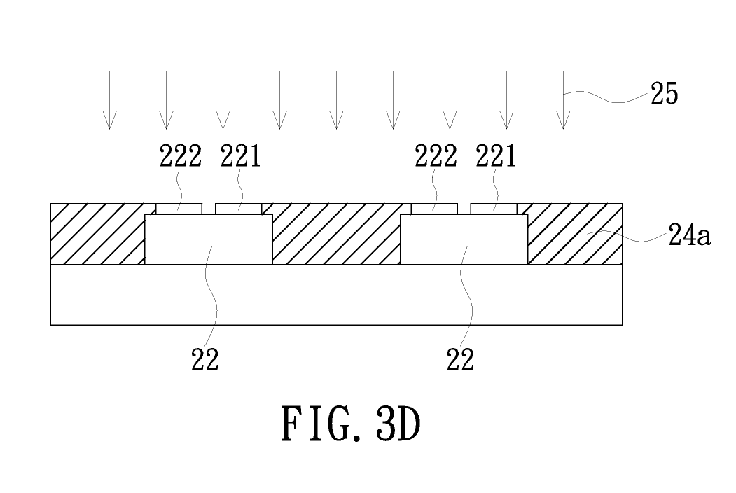

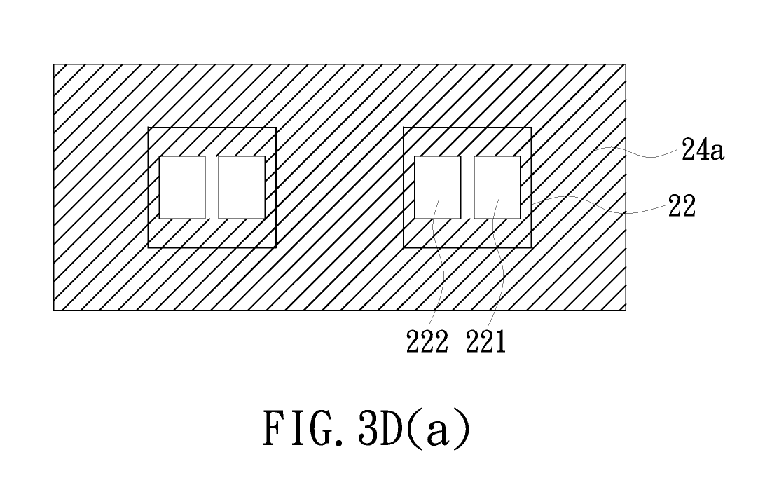

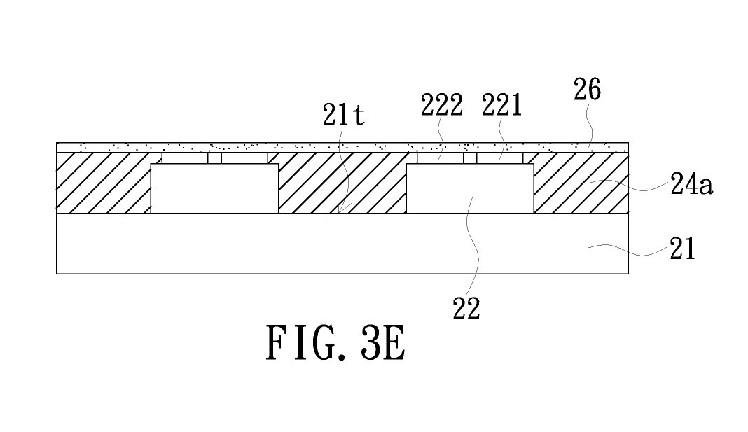

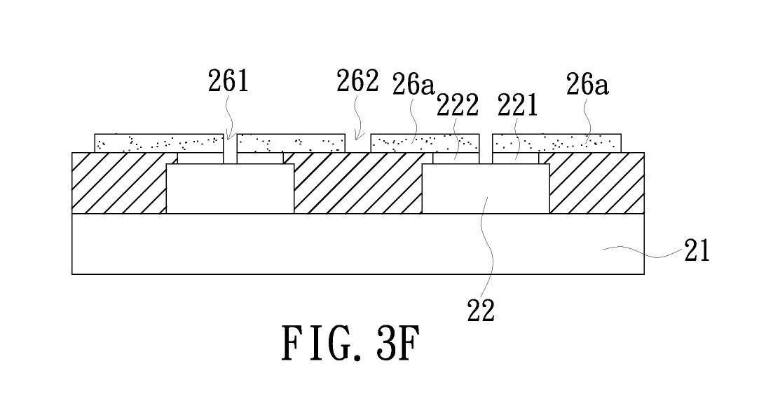

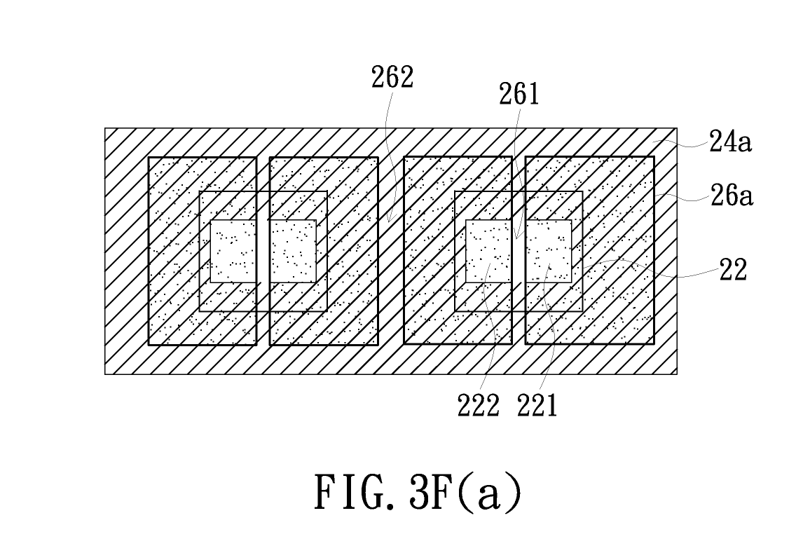

Hereinafter, specific descriptions of the art according to the invention are set forth accompanied with drawings in more details. By referring to FIGS. 3A-3G, respective packaging structures of light emitting diodes corresponding to the packaging method for light emitting diodes according to the invention are illustrated. First of all, as illustrated in FIG. 3A, a transparent substrate 21 with high transparency is prepared, which is made of any one material of transparent glass, transparent silicone, epoxy resin, silicone resin, polyimide, quartz material or any other appropriate transparent material. Here, although the cross section of the transparent substrate 21 as illustrated in FIG. 3A is in rectangle in shape, it is possible to modify the cross section of the transparent substrate 21, depending on an irradiating direction of light-emitting, as a combination of multiple trapezoids, a combination of multiple hemispheres, a combination of multiple arc surfaces and so on, further, it is possible to modify and unify the outline, if necessary. Then, as illustrated in FIG. 3B, at least two luminescent optoelectronic semiconductor chips 22 are provided on a surface 21t of the transparent substrate 21, wherein a respective light-emitting face 22b of the optoelectronic semiconductor chips 22 adjoin the surface 21t of the transparent substrate 21, each optoelectronic semiconductor chip 22 is provided with positive and negative electrodes 221 and 222, which are placed on the respective surface 22t of the optoelectronic semiconductor chips 22, as illustrated in FIG. 3B, and the electrodes 221 and 222 are placed on an opposite surface 22t to the adjoining surface of the optoelectronic semiconductor chip 22 and the transparent substrate 21. The optoelectronic semiconductor chip 22 is, preferably, a light-emitting diode (LED) die.

Thereafter, as illustrated in FIG. 3C-1, in the structure of light emitting diode according to the first embodiment, an isolator structure 23 is optionally provided on the surface 21t of the transparent substrate 21, wherein the isolator structure 23 surrounds and encircles respective optoelectronic semiconductor chips 22, and then, an insulating layer 24 is disposed on the surface 21t of the transparent substrate 21, which is filled within the isolator structure 23 and the optoelectronic semiconductor chips 22. Heights of the isolator structure 23 and the insulating layer 24 from the surface 21t of the transparent substrate 21 are substantially equal to or larger than that of the optoelectronic semiconductor chip 22, including the electrodes 221 and 222, therefrom, that is, the insulating layer 24 is allowed, at least, to overlay on the surface 21t of the transparent substrate 21 and lateral surfaces of the optoelectronic semiconductor chips 22 perpendicular to the surface 21t. The isolator structure 23 is not only adapted to shelter the optoelectronic semiconductor chips 22 on its periphery, but also to be functioned as a reflective layer, for condensing light from lateral surfaces and interfaces of the chips and reflecting or refracting the same in a desired direction. Although a cross section of the isolator structure 23 in rectangular shape is illustrated in FIG. 3C-1, it is possible to modify the cross section thereof desirably, such as trapezoid and so on, besides, it can be made of a material different from that of the transparent substrate 21, e.g. transparent or nontransparent materials, including glass material, silicone, polyester material, oxides, nitrides and so on, and made by any one process of spin-coating, photolithography, printing, chemical vapor deposition (CVD), lithography and so on. The material of the insulating layer 24 may be a photoresist material, polyester, oxides, metal oxides, nitrides and so on, and made by any one process of lamination, dispensing, spraying, coating and so on. Alternatively, in the structure of light emitting diode according to the second embodiment, as illustrated in FIG. 3C-2, the insulating layer 24 is immediately provided thereon, and the insulating layer 24 and the optoelectronic semiconductor chips 22 adjoin and overlay on the surface 21t of the transparent substrate 21. For facilitating description, as illustrated in FIG. 3C-2, it takes such an embodiment, i.e. immediately providing the insulating layer 24 thereon and overlaying on the electrodes 221, 222, the optoelectronic semiconductor chips 22 and the transparent substrate 21, as an example for describing subsequent processes.

In addition to the above-mentioned methods adapted to produce or fabricate the isolator structure 23, the isolator structure 23 can also be formed as a portion of the transparent substrate 21, such as an integrated configuration (integrated material layer) with the transparent substrate 21, and with such a configuration, the isolator structure 23 and the transparent substrate 21 can be made of the same material, and it is unnecessary to conduct the manufacturing process of the isolator structure 23.

As illustrated in FIG. 3D, a lithography 25 is conducted on the existing insulating layer 24, so that a patterned insulating layer 24a is produced, allowing the electrodes 221 and 222 to be exposed from the patterned insulating layer 24a, as illustrated in FIG. 3D (a), that is a top-side view of the structure of light emitting diode as illustrated in FIG. 3D; here, only two optoelectronic semiconductor chips 22 on the transparent substrate 21 are schematically illustrated in FIG. 3D (a) for description. After providing a metal layer 26, as illustrated in FIG. 3E, which is overlaid on the optoelectronic semiconductor chips 22 and the patterned insulating layer 24a, atop the surface 21t of the transparent substrate 21, the positive and negative electrodes 221 and 222 of all of the optoelectronic semiconductor chips 22 are electrically connected therewith. Then, the metal layer 26 is patterned, so that the metal layer 26 is provided separately on at least two metal patterns (not illustrated), and each metal pattern is merely electrically connected with only one electrode, serving as a seed layer of subsequent wiring process. Hereinafter, plating is conducted, so that the patterned metal layer 26 is so thickened as to serve as a plurality of metal soldering pads 26a, as illustrated in FIG. 3F. As illustrated in FIG. 3F (a), that is a top-side view of the structure of light emitting diode as illustrated in FIG. 3F, the metal soldering pads 26a are separated from each other and provided on respective electrodes 221 and 222, so that a plurality of separation regions 261 are produced therebetween, while a plurality of separation regions 262 are produced between the adjoining optoelectronic semiconductor chips 22.

Eventually, as illustrated in FIG. 3G, dicing is conducted along the separation regions 262, so that the respective optoelectronic semiconductor chips 22 are separated and the packaging structure of light emitting diode is accomplished.

The packaging structure of light emitting diode, as produced by the above-described packaging processes, at least comprises a transparent substrate 21, a plurality of optoelectronic semiconductor chips 24, which are placed on the surface 21t of the transparent substrate 21 and provided with positive and negative electrodes 221 and 222 respectively, a patterned insulating layer 24a which is placed on the surface 21t of the transparent substrate 21 and encircles and encapsulates the lateral surfaces of the optoelectronic semiconductor chips 22, and two metal soldering pads 26a separated from each other, which are provided on the opposite surface to the adjoining surface of the positive and negative electrodes 221 and 222 and the transparent substrate 21.

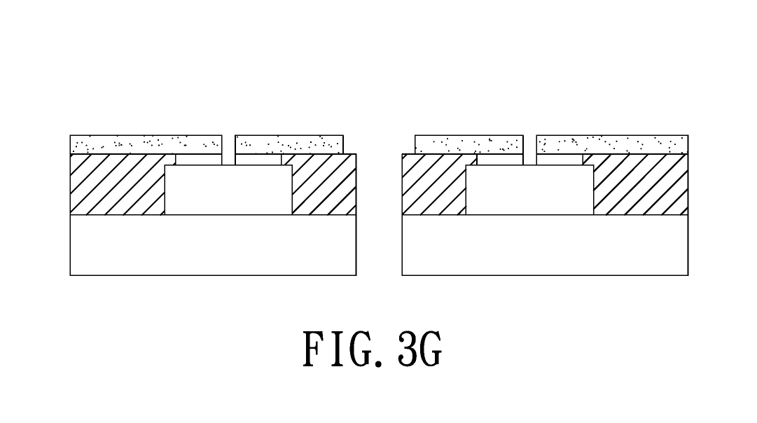

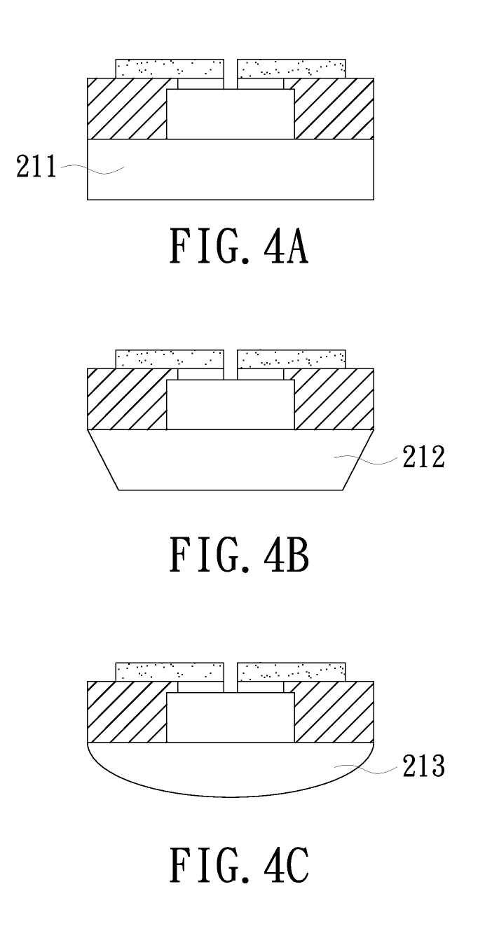

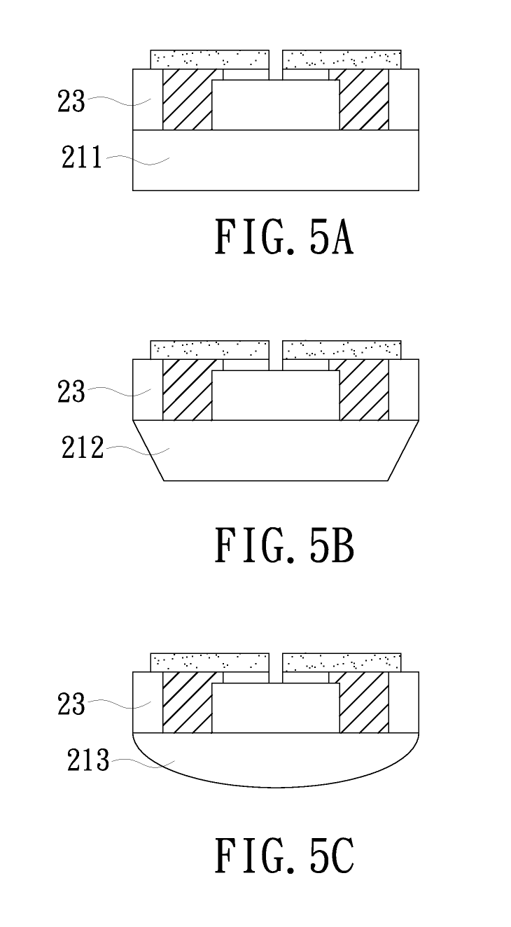

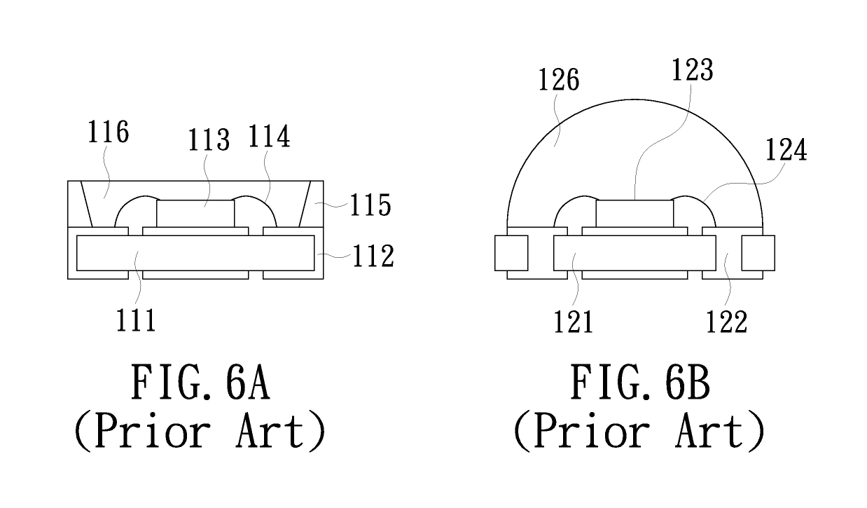

Moreover, in above-described packaging processes according to the invention, it is unnecessary for the transparent substrate 21 to experience a patterning process, and thus, in comparison with the conventional technologies, in which the patterned substrate 111 or 121 must be prepared in advance, it is possible to achieve the effects of time-saving and cost-saving. Also, it is needless to say, depending on the desired irradiating directions of light-emitting, it is also possible to conduct the patterning process on the transparent substrate 21, according to the invention, prior to the packaging processes, for example, the transparent substrate 21 may be so patterned as to produce one packaging structure with a cross section in the shape of trapezoid, arc-section, semi-circular and so on, with an appearance of quadrangular pyramid, camber, hemisphere and so on, depending on the practical demands, instead of two specific patterns in the conventional technologies. It is possible to alternatively adopt the packaging processes methods as illustrated in FIGS. 4A-4C and FIGS. 5A-5C, depending on various aspects derived from requirements to be meet, such as the desired irritating direction and field angle of light-emitting or light emittance, the existence or presence of the isolator structure and/or the shape thereof. The aspects as illustrated in FIGS. 4A-4C are not provided with an isolator structure, that is, modified aspects according to the structure of second embodiment. Besides, the aspects as illustrated in FIGS. 5A-5C are provided with the rectangular-cross-sectional isolator structure 23, that is, modified aspects according to the structure of first embodiment. Here, the aspects as illustrated in FIGS. 4A and 5A, the aforementioned transparent substrate 21 has not experienced patterned processes, and thus, the packaging structure will be in the shape of the transparent rectangular cuboid 211 after dicing, for modifying the irritating direction and field angle of light-emitting of the optoelectronic semiconductor chips; the aspects as illustrated in FIGS. 4B and 5B, the transparent substrate 21 has experienced patterned processes, and thus, the packaging structure will be in the shape of the transparent quadrangular pyramid 212 after dicing, for modifying the irritating direction and field angle of light-emitting of the optoelectronic semiconductor chips; further, the aspects as illustrated in FIGS. 4C and 5C, the transparent substrate 21 has experienced patterned processes, and thus, the (bottom portion of) packaging structure will be in the shape of the transparent round camber 213 after dicing, for modifying the irritating direction and field angle of light-emitting of the optoelectronic semiconductor chips. Although the specific descriptions are set forth in the embodiments, it should be understood that the disclosure needs not be limited to the above-described aspects and drawings, that is to say, the shape of transparent substrate 21, the existence of isolator structure and/or the shape thereof may be arbitrarily modified depending on desires.

According to the above-described packaging processes and packaging structure of light emitting diode, the transparent substrate 21 is not only used for carrying the optoelectronic semiconductor chip 22, but also functioned as a lens, on the contrary, in the conventional technologies, substrate and lens are essentially separated. Therefore, it is possible to modify the irritating direction of light-emitting of the optoelectronic semiconductor chips, without an increase in thickness and size of product, capable of achieving cost-saving and time-saving, and reduction in size of packaging structure as compared with the conventional technologies. Further, heat resulted from the operation of packaging chip can be dissipated by the metal soldering pads 26a in the optoelectronic semiconductor chip 22, and thus, the problem of poor heat dissipation efficiency in the conventional technologies can be solved. Moreover, since the metal soldering pads 26a are immediately electrically connected with the electrodes 221, 222 according to the invention, it can thus omit the extra metal wiring, resulting in advantage of cost-down, as well as obviation of the problems in the conventional technologies concurrently, such as fractures or displacement in the metal wiring, those will cause poor contact, unsteady quality of product and so on, eventually the yield of product is thus improved and assistance in production can be achieved.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A packaging structure of light emitting diodes, comprising:
a transparent substrate;
an optoelectronic semiconductor chip, provided with a light-emitting face and at least two electrodes, said at least two electrodes being provided on an opposite surface to an adjoining surface of said optoelectronic semiconductor chip and said transparent substrate, said light-emitting face being placed on said adjoining surface of said optoelectronic semiconductor chip and said transparent substrate;
an insulating layer, being provided on said transparent substrate, partially overlaid said at least two electrodes, said optoelectronic semiconductor chip and said transparent substrate; and
at least two metal soldering pads, being provided separately on said at least two electrodes, and electrically connected with said at least two electrodes respectively,
wherein a light emitted from said optoelectronic semiconductor chip penetrates through said transparent substrate.

2. The packaging structure of light emitting diodes according to claim 1, wherein said transparent substrate is made of glass.

3. The packaging structure of light emitting diodes according to claim 1, wherein said transparent substrate is a rectangular cuboid, for modifying an irradiating direction of said light emitted from said optoelectronic semiconductor chip.

4. The packaging structure of light emitting diodes according to claim 1, wherein said transparent substrate is a quadrangular pyramid, for modifying an irradiating direction of said light emitted from said optoelectronic semiconductor chip.

5. The packaging structure of light emitting diodes according to claim 1, wherein said transparent substrate is an arc-section cuboid, for modifying an irradiating direction of said light emitted from said optoelectronic semiconductor chip.

6. The packaging structure of light emitting diodes according to claim 1, further providing with an isolator structure, said isolator structure being provided on the periphery of said insulating layer so as to encircle said optoelectronic semiconductor chip.

7. The packaging structure of light emitting diodes according to claim 6, wherein said transparent substrate is a rectangular cuboid, for modifying an irradiating direction of said light emitted from said optoelectronic semiconductor chip.

8. The packaging structure of light emitting diodes according to claim 6, wherein said transparent substrate is a quadrangular pyramid, for modifying an irradiating direction of said light emitted from said optoelectronic semiconductor chip.

9. The packaging structure of light emitting diodes according to claim 6, wherein said transparent substrate is an arc-section cuboid, for modifying an irradiating direction of said light emitted from said optoelectronic semiconductor chip.

10. The packaging structure of light emitting diodes according to claim 6, wherein said isolator structure is provided on said transparent substrate via any one method of printing, dispensing or lithography.

11. A packaging method for light emitting diodes, comprising the steps of:
(A) preparing a transparent substrate with high transparency;
(B) providing an optoelectronic semiconductor chip on a surface of said transparent substrate, said optoelectronic semiconductor chip being provided with a light-emitting face and at least two electrodes, said at least two electrodes being provided on an opposite surface to a joining surface of said optoelectronic semiconductor chip and said transparent substrate, said light-emitting face being placed on said joining surface of said optoelectronic semiconductor chip and said transparent substrate, wherein a light emitted from said optoelectronic semiconductor chip penetrates through said transparent substrate;
(C) providing an insulating layer on said transparent substrate, so as to partially overlay said at least two electrodes, said optoelectronic semiconductor chip and said transparent substrate; and
(D) providing at least two metal soldering pads separately on said at least two electrodes, and said at least two metal soldering pads being electrically connected with said at least two electrodes respectively.

12. The packaging method for light emitting diodes according to claim 11, wherein said transparent substrate is made of glass.

13. The packaging method for light emitting diodes according to claim 11, further comprising a step of:
after the step (B), providing an isolator structure on said transparent substrate so as to encircle said optoelectronic semiconductor chip.

14. The packaging method for light emitting diodes according to claim 13, wherein said isolator structure is provided on said transparent substrate via any one method of printing, dispensing or lithography.
